(19) United States
(12) Patent Application Publication
(10) Pub. No.: US 2018/0330669 A1
(43) Pub. Date: Nov. 15, 2018

(54) DISPLAY PANEL, DISPLAY DEVICE AND DISPLAY DRIVING METHOD

(71) Applicants: BOE TECHNOLOGY GROUP CO., LTD., Beijing (CN); ORDOS YUANSHENG OPTOELECTRONICS CO., LTD., Inner Mongolia (CN)

(72) Inventor: Kening ZHENG, Beijing (CN)

(73) Assignees: BOE TECHNOLOGY GROUP CO., LTD., Beijing (CN); ORDOS YUANSHENG OPTOELECTRONICS CO., LTD., Inner Mongolia (CN)

(21) Appl. No.: 15/936,502

(22) Filed: Mar. 27, 2018

(30) Foreign Application Priority Data
May 11, 2017 (CN) 201710330852.0

(51) Int. Cl. G09G 3/3258; H01L 27/32

(52) U.S. Cl. CPC G09G 3/3258; G09G 2320/0295; G09G 2320/041; H01L 27/3274

(57) ABSTRACT

A display panel is provided, which includes multiple sub-pixel units, a temperature sensor and a power control module. The temperature sensor is connected with the power control module and used to detect a temperature of a temperature detection region of the temperature sensor and output the detected temperature to the power control module. The power control module is used to inquire a preset temperature and cathode voltage relationship table based on the temperature and control a cathode voltage for at least one sub-pixel unit located in the temperature detection region, upon receipt of the temperature. A display device and a display driving method are further provided.

### CROSS-REFERENCE TO RELATED APPLICATION

This application claims priority to Chinese Patent Application No. 201710330852.0 filed on May 11, 2017, which is incorporated herein by reference in its entirety.

### TECHNICAL FIELD

The present disclosure relates to the field of display technology, in particular, to a display panel, a display device and a display driving method.

### BACKGROUND

Ever since Qingyun Deng discovered heterojunction Organic Light-Emitting Diode (OLED) in 1987, OLED technology has been rapidly developed. OLED becomes a development trend for next-generation display since OLED display has advantages such as lighter weight and smaller thickness, lower power consumption, higher contrast ratio, wider color gamut and capability of flexible displaying when compared with Liquid Crystal Display (LCD).

High and low temperature reliability test needs to be performed on the OLED display in mass production, for example, the OLED display needs to operate 240 hours at a high temperature of 60° C. and operate 120 hours at a low temperature of −30° C. Due to the influence of temperature on material mobility, voltages corresponding to brightnesses of red, green and blue (RGB) monochromatic lights decomposed from white balance vary with temperature. However, conventional Integrated Circuits (ICs) do not have a function of adjusting a cathode voltage Vss based on sensing the temperature. Due to lack of such function of the IC, the OLED display may be subjected to white light deviation when operating in high temperature or low temperature, thereby adversely affecting the display effect.

### SUMMARY

Embodiments of the present disclosure provide a display panel, a display device and a display driving method, to prevent white image deviation in a high or low temperature operating environment.

In one aspect, the present disclosure provides a display panel, including multiple sub-pixel units, a temperature sensor and a power control module.

The temperature sensor is connected with the power control module and used to detect a temperature of a temperature detection region of the temperature sensor and output the detected temperature to the power control module.

The power control module is used to inquire a preset temperature and cathode voltage relationship table based on the temperature and control a cathode voltage for at least one sub-pixel unit located in the temperature detection region, upon receipt of the temperature.

Optionally, the display panel is provided with only one temperature sensor and the temperature detection region of the only one temperature sensor covers a whole display region of the display panel.

Optionally, the display panel is provided with multiple temperature sensors, the temperature detection regions of the multiple temperature sensors cover a whole display region of the display panel, and each sub-pixel unit is only located in the temperature detection region of one temperature sensor, and

the power control module is used to receive temperatures sent by the multiple temperature sensors, select a highest temperature from the temperatures sent by the multiple temperature sensors, inquire the preset temperature and cathode voltage relationship table based on the highest temperature, and control the cathode voltage for at least one sub-pixel unit located in the temperature detection region of each of the multiple temperature sensors.

Optionally, the display panel is provided with multiple temperature sensors, the temperature detection regions of the multiple temperature sensors cover a whole display region of the display panel, and each sub-pixel unit is only located in the temperature detection region of one temperature sensor, and

the power control module is used to receive temperatures sent by the multiple temperature sensors, inquire the preset temperature and cathode voltage relationship table respectively based on the temperatures sent by the multiple temperature sensors, and control the cathode voltage for at least one sub-pixel unit located in the temperature detection region of each of the multiple temperature sensors respectively.

Optionally, multiple pixel units are provided in the temperature detection region of the temperature sensor, and each of the multiple pixel units comprises a red sub-pixel unit, a green sub-pixel unit and a blue sub-pixel unit; and

the power control module is used to control the cathode voltage for at least one of the red sub-pixel unit, the green sub-pixel unit and the blue sub-pixel unit according to the preset temperature and cathode voltage relationship table.

Optionally, the power control module is used to control only the cathode voltage for the blue sub-pixel unit according to the preset temperature and cathode voltage relationship table.

Optionally, the red sub-pixel unit includes a first drive transistor and a red light electroluminescent unit, a control electrode of the first drive transistor is connected with a first potential terminal, a first electrode of the first drive transistor is connected with a second potential terminal, a second electrode of the first drive transistor is connected with the red light electroluminescent unit, and the red light electroluminescent unit is connected with the power control module;

the green sub-pixel unit includes a second drive transistor and a green light electroluminescent unit, a control electrode of the second drive transistor is connected with the first potential terminal, a first electrode of the second drive transistor is connected with the second potential terminal, a second electrode of the second drive transistor is connected with the green light electroluminescent unit, and the green light electroluminescent unit is connected with the power control module; and

the blue sub-pixel unit includes a third drive transistor and a blue light electroluminescent unit, a control electrode of the third drive transistor is connected with the first potential terminal, a first electrode of the third drive transistor is connected with the second potential terminal, a second electrode of the third drive transistor is connected with the blue light electroluminescent unit, and the blue light electroluminescent unit is connected with the power control module.

Optionally, the red light electroluminescent unit, the green light electroluminescent unit and the blue light electroluminescent unit are organic light emitting diodes, an anode of each organic light emitting diode is connected with the corresponding drive transistor, and a cathode of each organic light emitting diode is connected with the power control module.

In another aspect, the present disclosure provides a display device, which includes the above display panel.

In further another aspect, the present disclosure provides a display driving method, which includes:

detecting a temperature in a temperature detection region of a temperature sensor; and

inquiring a preset temperature and cathode voltage relationship table based on the detected temperature and controlling a cathode voltage for at least one sub-pixel unit within the temperature detection region.

Optionally, the step of inquiring the preset temperature and cathode voltage relationship table based on the detected temperature and controlling the cathode voltage for the at least one sub-pixel unit within the temperature detection region includes:

inquiring the preset temperature and cathode voltage relationship table and decreasing the cathode voltage for the at least one sub-pixel unit within the temperature detection region, in a case that the detected temperature increases; and inquiring the preset temperature and cathode voltage relationship table and increasing the cathode voltage for the at least one sub-pixel unit within the temperature detection region, in a case that the detected temperature decreases.

### BRIEF DESCRIPTION OF THE DRAWINGS

FIG. 1a is a schematic diagram of an OLED light-emitting module;

FIG. 1b is a diagram of I-V output curves of an OTFT in condition of different Vgs and I-V curves of an OLED in condition of different temperatures;

FIG. 2a is a table of I-V data of an OLED in condition of different temperatures;

FIG. 2b is a diagram of I-V curves corresponding to FIG. 2a;

FIG. 3 is a schematic diagram of a display panel according to some embodiments of the present disclosure;

FIG. 4 is a diagram of I-V output curves of an OTFT in condition of different Vgs and I-V curves of an OLED in condition of different temperatures according to some embodiments of the present disclosure;

FIG. 5 is a table of I-V data of an OLED at different temperatures (−30° C. and 60° C.) and before and after changing Vss according to some embodiments of the present disclosure;

FIG. 6 schematically illustrates controlling, by a power control IC, an I-V curve at a high temperature of 60° C. to approximate an I-V curve at a temperature of 25° C. according to some embodiments of the present disclosure;

FIG. 7 schematically illustrates controlling, by a power control IC, an I-V curve at a low temperature of −30° C. to approximate the I-V curve at the temperature of 25° C. according to some embodiments of the present disclosure;

FIG. 8 is a schematic diagram of one pixel unit of a display panel according to some embodiments of the present disclosure;

FIG. 9 is a schematic diagram of a display panel according to some embodiments of the present disclosure;

FIG. 10 is a schematic diagram of a display panel according to some embodiments of the present disclosure;

FIG. 11 is a schematic diagram of a display panel according to some embodiments of the present disclosure; and

FIG. 12 is a flow chart of a display driving method according to some embodiments of the present disclosure.

### DETAILED DESCRIPTION

When an OLED device operates under high or low temperature, mobility of an organic material of the OLED device may decrease or increase due to characteristics of the organic material; degrees of decreasement or increasement of operating voltages Vops for monochromatic R/G/B sub-pixels are different, and the Vop for the monochromatic blue sub-pixel has a largest decreasement or increasement. Conventional back plate circuits do not take measures to avoid the above problem and conventional ICs do not have the function of adjusting the voltage as the ambient temperature changes. As increasing or decreasing degrees of brightnesses for R/G/B sub-pixels may be different, the OLED display may be subjected to white light deviation when operating in high or low temperature environment.

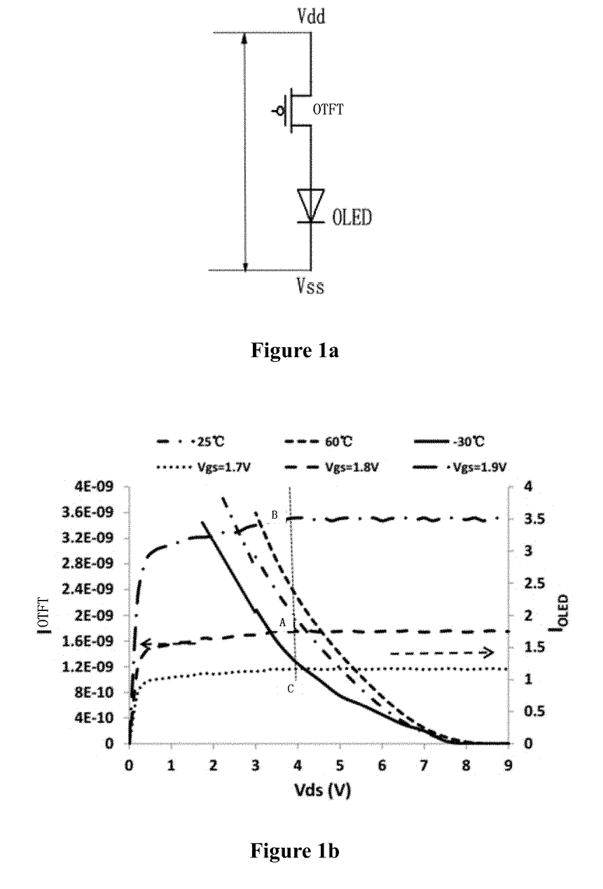

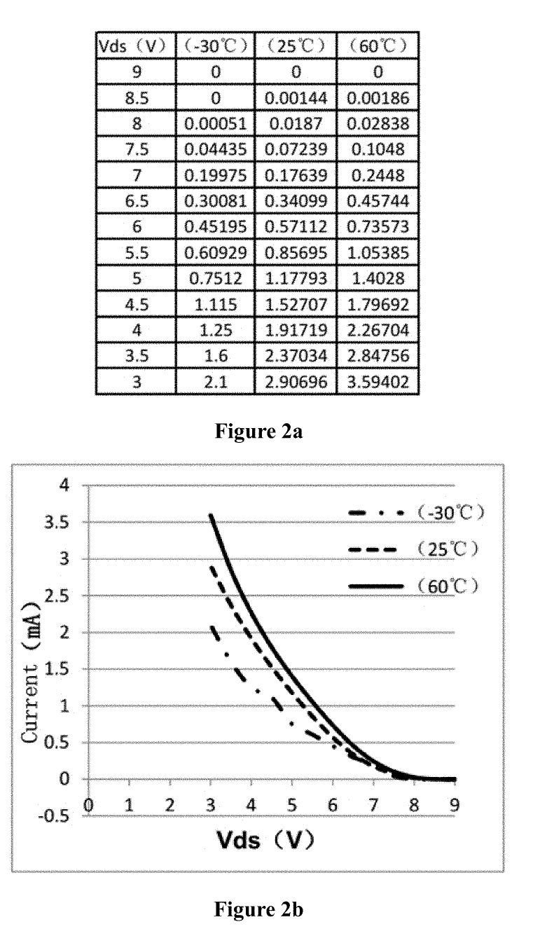

FIG. 1a is a schematic diagram of an OLED light-emitting module, which includes an organic thin film transistor (OTFT) and an OLED. FIG. 1b is a diagram of I-V output curves of the OTFT in condition of different Vgs (1.7V, 1.8V and 1.9V) and I-V curves of the OLED in condition of different temperatures (−30° C., 25° C. and 60° C.). FIG. 2a is a table of I-V data of the OLED in condition of a constant Vss and different temperatures. FIG. 2b is a diagram of I-V curves of the OLED corresponding to FIG. 2a.

As can be seen from FIG. 1b, I-V curves of OLED and I-V output curves of OTFT in condition of an identical operating voltage and different temperatures (−30° C., 25° C. and 60° C.) intersect at points B (Vgs=1.9V), A (Vgs=1.8V) and C (Vgs=1.7V), and a relationship of currents Iₐ, I_{b} and I_{c} at the corresponding points satisfies that I_{b}>Iₐ>I_{c}. Due to characteristics of OLED materials, a brightness variation is proportional to a variation of an OLED current, that is, an OLED brightness is increased as the temperature rises. However, as the R/G/B sub-pixels are made of different materials and have different thicknesses and monochromatic brightness increments are different, brightnesses and color coordinates of the R/G/B sub-pixels in condition of different temperatures are different, which results in white image deviation as the temperature changes. As can be seen from FIG. 2b, the OLED current is inversely proportional to Vds, i.e., Vdd subtracted by Vss; hence, the influence of the temperature variation on the OLED current may be neutralized by adjusting Vss. However, since existing ICs do not have the function of adjusting Vss by sensing the temperature variation, the OLED display may be subjected to white image deviation due to the temperature variation of an operating environment.

Some embodiments of the present disclosure provide a method which can alleviate white image deviation caused by temperature variation. In the method, a temperature sensor is arranged in a display panel, an ambient temperature sensed by the temperature sensor is sent to a power control integrated circuit (IC), Vss is decreased as the ambient temperature increases or increased as the ambient temperature decreases, thereby changing the difference between Vdd and Vss and preventing white image deviation in high or low temperature.

In order to make technical solutions and advantages of the present disclosure clearer, hereinafter embodiments of the present disclosure will be illustrated in detail in conjunction with drawings. It should be noted that, in case of no conflict, the embodiments in the present disclosure and features in the embodiments can be arbitrarily combined with each other.

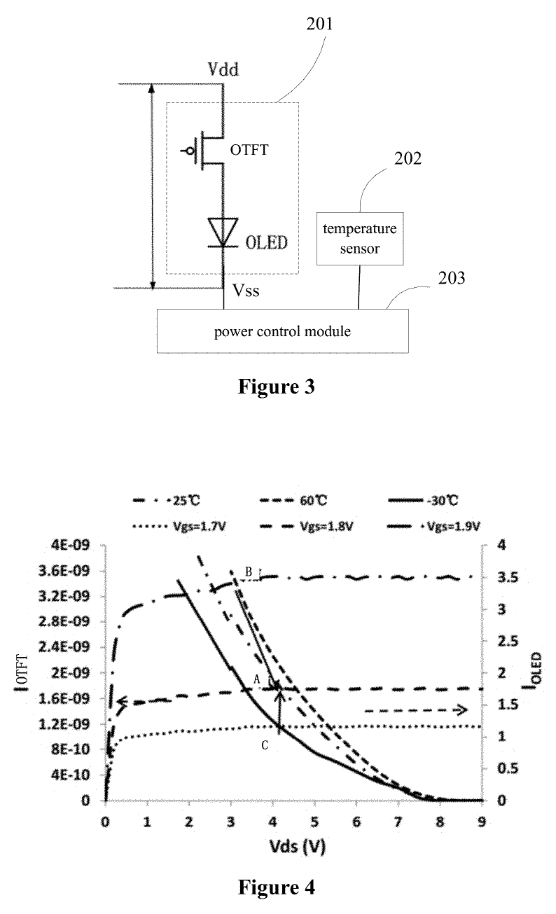

FIG. 3 is a schematic diagram of a display panel according to some embodiments of the present disclosure. As shown in FIG. 3, the display panel 200 includes multiple sub-pixel units 201, a temperature sensor 202 and a power control module 203.

The temperature sensor 202 is connected with the power control module 203, and used to detect a temperature of a temperature detection region of the temperature sensor 202 and output the detected temperature to the power control module 203.

The power control module 203 is used to inquire a preset temperature and cathode voltage relationship table based on the temperature and control a cathode voltage for each sub-pixel unit 201 located in the temperature detection region, upon receipt of the temperature.

Since influences caused by temperature on currents of respective sub-pixel units are different, brightness variations of the respective sub-pixel units as the temperature changes are different and a white image may be subjected to an obvious deviation. In the method according to the embodiments, cathode voltages for different sub-pixel units can be adjusted respectively based on changed temperature, such that the brightness variations of respective sub-pixel units of the display panel can be the same, thus avoiding the white image deviation.

In inquiring the preset temperature and cathode voltage relationship table based on the temperature and controlling the cathode voltage for each sub-pixel unit 201 located in the temperature detection region, the power control module 203 is specifically used to: inquire the preset temperature and cathode voltage relationship table and decrease the cathode voltage for each sub-pixel unit located in the temperature detection region, in a case that the received temperature increases; and inquire the preset temperature and cathode voltage relationship table and increase the cathode voltage for each sub-pixel unit located in the temperature detection region, in a case that the received temperature decreases.

With the display panel according to the embodiments, a voltage different between Vdd and Vss for a light-emitting module in the sub-pixel unit 201 can be automatically adjusted based on the ambient temperature, thereby preventing white image deviation in a high or low temperature operating environment.

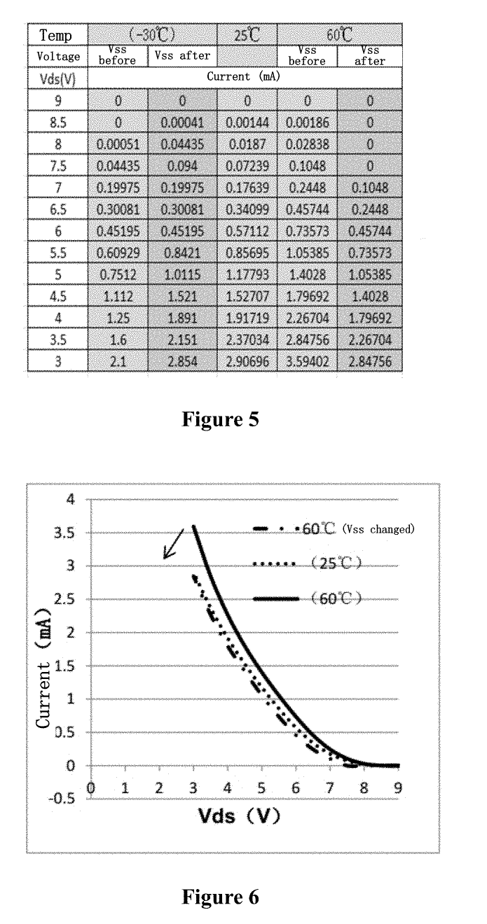

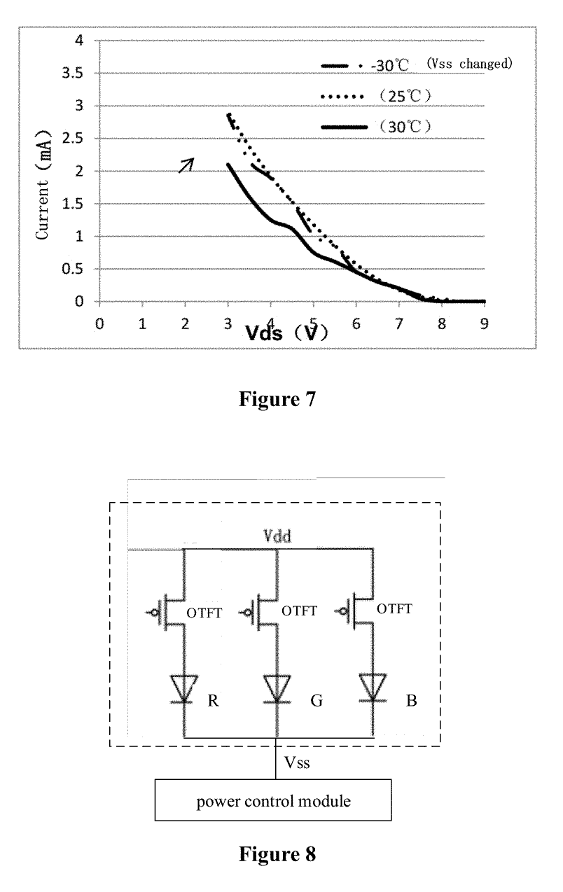

FIG. 4 is a diagram of I-V output curves of an OTFT in condition of different Vgs and I-V curves of an OLED in condition of different temperatures according to some embodiments of the present disclosure. FIG. 5 is a table of I-V data of the OLED at different temperatures (−30° C. and 60° C.) and before and after changing Vss according to some embodiments of the present disclosure. FIG. 6 schematically illustrates controlling, by a power control IC, an I-V curve at a high temperature of 60° C. to approximate an I-V curve at a temperature of 25° C. according to some embodiments of the present disclosure. FIG. 7 schematically illustrates controlling, by a power control IC, an I-V curve at a low temperature of −30° C. to approximate the I-V curve at the temperature of 25° C. according to some embodiments of the present disclosure.

The temperature sensor senses that the ambient temperature becomes lower in a case of a low temperature environment, and in this case, the power control module 203 automatically decreases Vss for a corresponding sub-pixel unit, that is, increases the voltage difference between Vdd and Vss. For example, when the temperature is decreased from a room temperature 25° C. to −30° C., as shown in FIGS. 4 and 7, an I-V curve of the OLED at the low temperature of −30° C. is shifted to the right by decreasing Vss. In this way, the shifted I-V curve of the OLED at the low temperature of −30° C. and an I-V curve of OLED at the room temperature of 25° C. are approximately the same, and accordingly, an intersection point of the I-V curve of the OLED and an I-V output curve of OTFT moves from point C to point A. That is, an operating voltage and an operating current of OLED at the low temperature are changed to be substantially the same as those of the OLED at the room temperature by decreasing Vss, which avoids the white image deviation due to decreased material mobility under low temperature.

The temperature sensor senses that the ambient temperature becomes higher in a case of a high temperature environment, and in this case, the power control module 203 automatically increases Vss for a corresponding sub-pixel unit to decrease the voltage difference between Vdd and Vss. For example, when the temperature is increased from the room temperature 25° C. to 60° C., as shown in FIGS. 4 and 6, an I-V curve of the OLED at the high temperature of 60° C. is shifted to the left by increasing Vss. In this way, the shifted I-V curve of the OLED at the high temperature of 60° C. and the I-V curve of OLED at the room temperature of 25° C. are approximately the same, and accordingly, the intersection point of the I-V curve of the OLED and the I-V output curve of the OTFT moves from point B to point A. That is, an operating voltage and an operating current of the OLED at the high temperature are changed to be substantially the same as those of the OLED at the room temperature by increasing Vss, which avoids the white image deviation of the OLED display under high temperature.

According to some embodiments of the present disclosure, the display panel includes multiple pixel units. More than one pixel unit is included in the temperature detection region of the temperature sensor, and each of the pixel units includes a red sub-pixel unit, a green sub-pixel unit and a blue sub-pixel unit, as shown in FIG. 8.

The red sub-pixel unit includes a first drive transistor and a red light electroluminescent unit, a control electrode of the first drive transistor is connected with a first potential terminal, a first electrode of the first drive transistor is connected with a second potential terminal, a second electrode of the first drive transistor is connected with the red light electroluminescent unit, and the red light electroluminescent unit is connected with the power control module.

The green sub-pixel unit includes a second drive transistor and a green light electroluminescent unit, a control electrode of the second drive transistor is connected with the first potential terminal, a first electrode of the second drive transistor is connected with the second potential terminal, a second electrode of the second drive transistor is connected with the green light electroluminescent unit, and the green light electroluminescent unit is connected with the power control module.

The blue sub-pixel unit includes a third drive transistor and a blue light electroluminescent unit, a control electrode of the third drive transistor is connected with the first potential terminal, a first electrode of the third drive transistor is connected with the second potential terminal, a second electrode of the third drive transistor is connected with the blue light electroluminescent unit, and the blue light electroluminescent unit is connected with the power control module.

The first potential terminal and the potential terminal may both be Vdd.

The red light electroluminescent unit, the green light electroluminescent unit and the blue light electroluminescent unit may be organic light emitting diodes, an anode of each organic light emitting diode is connected with a corresponding drive transistor, and a cathode of each organic light emitting diode is connected with the power control module.

A corresponding temperature and voltage relationship table is pre-stored in the power control module based on characteristics of a relationship between the temperature and the voltage for each sub-pixel unit. Since a power voltage Vdd is constant, the power control module may adjust a cathode voltage Vss of at least one of the red sub-pixel, the green sub-pixel and the blue sub-pixel in each pixel unit according to the preset temperature and voltage relationship tables, thereby adjusting the difference between Vdd and Vss and avoiding the white image deviation under a high or low temperature.

Considering that influence caused by the temperature on the brightness of the blue sub-pixel units is greater than red and green sub-pixel units, in some embodiments of the present disclosure, the power control module may control the cathode voltages of only the blue sub-pixel units according to the preset temperature and voltage relationship tables.

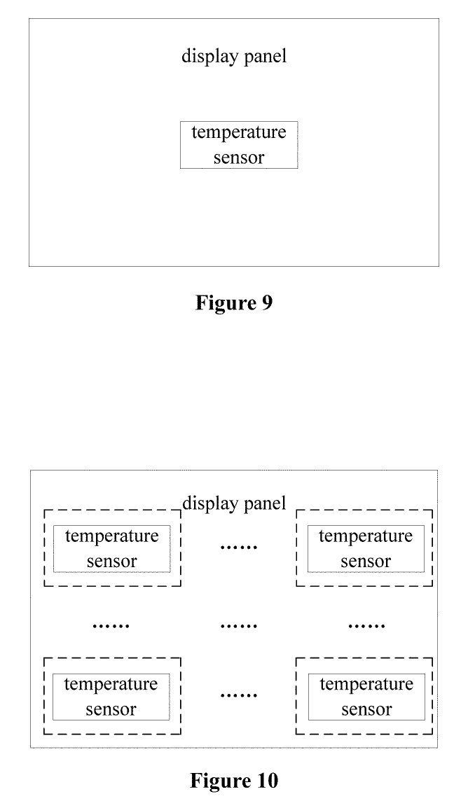

In some embodiments of the present disclosure, the display panel is provided with only one temperature sensor, which is arranged in a central region of the display panel as shown in FIG. 9. Here, the temperature detection region of the temperature sensor covers a whole display region of the display panel.

In some embodiments of the present disclosure, the display panel is provided with multiple temperature sensors uniformly arranged in the display panel as shown in FIG. 10. The temperature detection regions of the multiple temperature sensors can cover the whole display region of the display panel; hence, ambient temperatures of all sub-pixel units of the display panel can be detected by the multiple temperature sensors. Due to the preparation process (such as uniformity of each film, uniform resistance and uniform voltage drop of a back plate) of an OLED display panel sample in a high or low temperature operating environment, the color deviation may occur at any positions. Accordingly, the temperature sensors are arranged uniformly to monitor possible temperature variations at different position of the entire display panel. Each sub-pixel unit may only be located in the temperature detection region of one temperature sensor and a temperature detected by the temperature sensor is just the ambient temperature of the sub-pixel unit.

The power control module receives the temperatures sent by the multiple temperature sensors and the temperatures detected by respective temperature sensors may be different. Since higher temperature may cause greater influence on the brightnesses of the monochromatic light electroluminescent units, the preset temperature and voltage relationship tables may be inquired based on a highest temperature of the temperatures detected by the respective temperature sensors to control the cathode voltages for the monochromatic light electroluminescent units.

In some embodiments of the present disclosure, the power control module may receive temperatures sent by the multiple temperature sensors, inquire the preset temperature and cathode voltage relationship tables respectively based on the temperatures detected by the multiple temperature sensors, and control the cathode voltages for the sub-pixel units respectively located in the temperature detection regions of the multiple temperature sensors. In this way, the sub-pixel units in each local region can be controlled independently from those in other local regions, thereby overcoming local region color deviation conveniently.

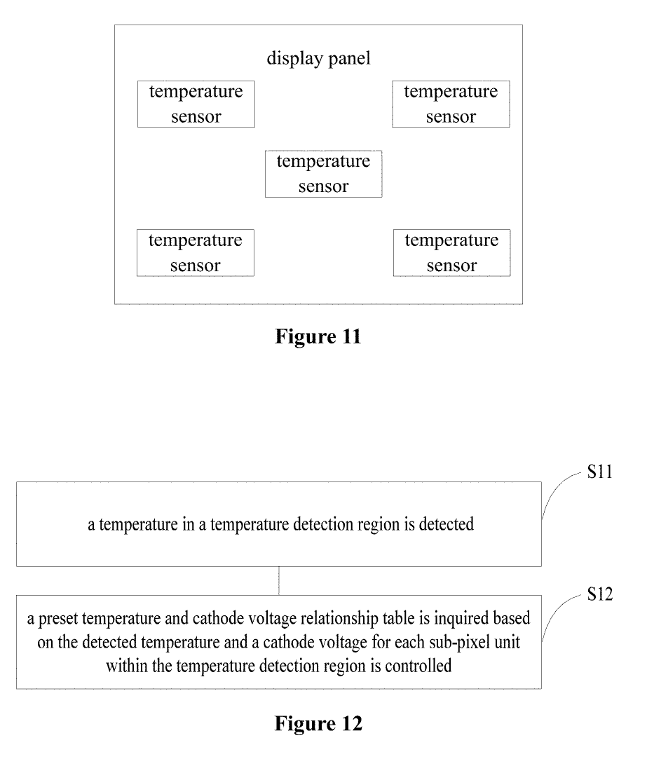

In order to reduce the number of electronic devices, in some embodiments of the present disclosure, five temperature sensors are used, where four temperature sensors are respectively arranged at four edges or four corners of the display panel and one temperature sensor is arranged in the central region of the display panel, as shown in FIG. 11.

The power control module receives the temperatures sent by the five temperature sensors, inquires the preset temperature and voltage relationship tables based on a highest temperature among temperatures detected by the five temperature sensors to control the cathode voltages for the sub-pixel units.

It should be noted that, in the case that the display panel is provided with multiple temperature sensors, temperature detection regions of respective temperature sensors can be partitioned based on actual locations where the respective temperature sensors are arranged in the display panel and shapes of the temperature detection regions are not specifically limited, as long as conditions that the temperature detection regions of all temperature sensors can cover the whole display region of the display panel and each sub-pixel unit is only located in the temperature detection region of one temperature sensor. For example, in the case that multiple temperature sensors are uniformly arranged, the temperature detection regions of the multiple temperature sensors can be reflected by dashed boxes arranged in a matrix as shown in FIG. 10.

Some embodiments of the present disclosure further provide a display device, which includes the display panel according to the above embodiments of the present disclosure. The principle of the display device to solve technical problem is similar to the foregoing display panel. Therefore, implementations of the display device can refer to foregoing implementations of the display panel, which are not repeated herein.

Some embodiments of the present disclosure further provide a display driving method. As shown in FIG. 12, the display driving method according to the embodiments includes steps S11 to S12.

In step S11, a temperature in a temperature detection region is detected.

In step S12, a preset temperature and cathode voltage relationship table is inquired based on the detected temperature and a cathode voltage for each sub-pixel unit within the temperature detection region is controlled.

In step S12, in a case that the detected temperature increases, the preset temperature and cathode voltage relationship table is inquired and the cathode voltage for each sub-pixel unit within the temperature detection region is decreased; and in a case that the detected temperature decreases, the preset temperature and cathode voltage relationship table is inquired and the cathode voltage for each sub-pixel unit within the temperature detection region is increased.

The principle of the display driving method to solve technical problem is similar to the foregoing display panel. Therefore, implementations of the display driving method can refer to foregoing implementations of the display panel, which are not repeated herein.

It can be understood by those skilled in the art that all or part of steps in the above method may be completed by hardware instructed by program instructions, which can be stored in a computer readable storage medium, such as a read-only memory, a disk or a CD. Optionally, all or part of steps in the above embodiments may also be achieved by one or more integrated circuits. Correspondingly, various modules or units can be achieved in a form of hardware or software. The present disclosure is not limited to any specific form of a combination of hardware and software.

The foregoing embodiments are only optional embodiments of the present disclosure, and the present disclosure may also include other various embodiments. Various modifications and transformations can be made by those skilled in the art without departing from the spirit and principle of the present disclosure, and these modifications and transformations shall also fall within the protection scope of the claims in the present disclosure.

What is claimed is:

1. A display panel, comprising a plurality of sub-pixel units, a temperature sensor and a power control module, wherein
the temperature sensor is connected with the power control module and configured to detect a temperature of a temperature detection region of the temperature sensor and output the detected temperature to the power control module; and
the power control module is configured to inquire a preset temperature and cathode voltage relationship table based on the temperature and control a cathode voltage for at least one sub-pixel unit located in the temperature detection region, upon receipt of the temperature.

2. The display panel according to claim 1, wherein
the display panel is provided with only one temperature sensor and the temperature detection region of the only one temperature sensor covers a whole display region of the display panel.

3. The display panel according to claim 1, wherein
the display panel is provided with a plurality of temperature sensors, the temperature detection regions of the plurality of temperature sensors cover a whole display region of the display panel, and each sub-pixel unit is only located in the temperature detection region of one temperature sensor; and
the power control module is configured to receive temperatures sent by the plurality of temperature sensors, select a highest temperature from the temperatures sent by the plurality of temperature sensors, inquire the preset temperature and cathode voltage relationship table based on the highest temperature, and control the cathode voltage for at least one sub-pixel unit located in the temperature detection region of each of the plurality of temperature sensors.

4. The display panel according to claim 1, wherein
the display panel is provided with a plurality of temperature sensors, the temperature detection regions of the plurality of temperature sensors cover a whole display region of the display panel, and each sub-pixel unit is only located in the temperature detection region of one temperature sensor; and
the power control module is configured to receive temperatures sent by the plurality of temperature sensors, inquire the preset temperature and cathode voltage relationship table respectively based on the temperatures sent by the plurality of temperature sensors, and control the cathode voltage for at least one sub-pixel unit located in the temperature detection region of each of the plurality of temperature sensors respectively.

5. The display panel according to claim 1, wherein
a plurality of pixel units is provided in the temperature detection region of the temperature sensor, and each of the plurality of pixel units comprises a red sub-pixel unit, a green sub-pixel unit and a blue sub-pixel unit; and
the power control module is configured to control the cathode voltage for at least one of the red sub-pixel unit, the green sub-pixel unit and the blue sub-pixel unit according to the preset temperature and cathode voltage relationship table.

6. The display panel according to claim 5, wherein:
the power control module is configured to control only the cathode voltage for the blue sub-pixel unit according to the preset temperature and cathode voltage relationship table.

7. The display panel according to claim 5, wherein
the red sub-pixel unit comprises a first drive transistor and a red light electroluminescent unit, a control electrode of the first drive transistor is connected with a first potential terminal, a first electrode of the first drive transistor is connected with a second potential terminal, a second electrode of the first drive transistor is connected with the red light electroluminescent unit, and the red light electroluminescent unit is connected with the power control module;
the green sub-pixel unit comprises a second drive transistor and a green light electroluminescent unit, a control electrode of the second drive transistor is connected with the first potential terminal, a first electrode of the second drive transistor is connected with the second potential terminal, a second electrode of the second drive transistor is connected with the green light electroluminescent unit, and the green light electroluminescent unit is connected with the power control module; and
the blue sub-pixel unit comprises a third drive transistor and a blue light electroluminescent unit, a control electrode of the third drive transistor is connected with the first potential terminal, a first electrode of the third drive transistor is connected with the second potential terminal, a second electrode of the third drive transistor is connected with the blue light electroluminescent unit, and the blue light electroluminescent unit is connected with the power control module.

8. The display panel according to claim 7, wherein:
the red light electroluminescent unit, the green light electroluminescent unit and the blue light electroluminescent unit are organic light emitting diodes, an anode of each organic light emitting diode is connected with a corresponding drive transistor, and a cathode of the each organic light emitting diode is connected with the power control module.

9. A display device, comprising a display panel,
wherein the display panel comprises: a plurality of sub-pixel units, a temperature sensor and a power control module,
wherein the temperature sensor is connected with the power control module and configured to detect a temperature of a temperature detection region of the temperature sensor and output the detected temperature to the power control module; and
wherein the power control module is configured to inquire a preset temperature and cathode voltage relationship table based on the temperature and control a cathode voltage for at least one sub-pixel unit located in the temperature detection region, upon receipt of the temperature.

10. The display device according to claim 9, wherein
the display panel is provided with only one temperature sensor and the temperature detection region of the only one temperature sensor covers a whole display region of the display panel.

11. The display device according to claim 9, wherein
the display panel is provided with a plurality of temperature sensors, the temperature detection regions of the plurality of temperature sensors cover a whole display region of the display panel, and each sub-pixel unit is only located in the temperature detection region of one temperature sensor; and
the power control module is configured to receive temperatures sent by the plurality of temperature sensors, select a highest temperature from the temperatures sent by the plurality of temperature sensors, inquire the preset temperature and cathode voltage relationship table based on the highest temperature, and control the cathode voltage for at least one sub-pixel unit located in the temperature detection region of each of the plurality of temperature sensors.

12. The display device according to claim 9, wherein
the display panel is provided with a plurality of temperature sensors, the temperature detection regions of the plurality of temperature sensors cover a whole display region of the display panel, and each sub-pixel unit is only located in the temperature detection region of one temperature sensor; and
the power control module is configured to receive temperatures sent by the plurality of temperature sensors, inquire the preset temperature and cathode voltage relationship table respectively based on the temperatures sent by the plurality of temperature sensors, and control the cathode voltage for at least one sub-pixel unit located in the temperature detection region of each of the plurality of temperature sensors respectively.

13. The display device according to claim 9, wherein
a plurality of pixel units is provided in the temperature detection region of the temperature sensor, and each of plurality of pixel units comprises a red sub-pixel unit, a green sub-pixel unit and a blue sub-pixel unit; and
the power control module is configured to control the cathode voltage for at least one of the red sub-pixel unit, the green sub-pixel unit and the blue sub-pixel unit according to the preset temperature and cathode voltage relationship table.

14. The display device according to claim 13, wherein
the power control module is configured to only control the cathode voltage for the blue sub-pixel unit according to the preset temperature and cathode voltage relationship table.

15. The display device according to claim 13, wherein
the red sub-pixel unit comprises a first drive transistor and a red light electroluminescent unit, a control electrode of the first drive transistor is connected with a first potential terminal, a first electrode of the first drive transistor is connected with a second potential terminal, a second electrode of the first drive transistor is connected with the red light electroluminescent unit, and the red light electroluminescent unit is connected with the power control module;
the green sub-pixel unit comprises a second drive transistor and a green light electroluminescent unit, a control electrode of the second drive transistor is connected with the first potential terminal, a first electrode of the second drive transistor is connected with the second potential terminal, a second electrode of the second drive transistor is connected with the green light electroluminescent unit, and the green light electroluminescent unit is connected with the power control module; and
the blue sub-pixel unit comprises a third drive transistor and a blue light electroluminescent unit, a control electrode of the third drive transistor is connected with the first potential terminal, a first electrode of the third drive transistor is connected with the second potential terminal, a second electrode of the third drive transistor is connected with the blue light electroluminescent unit, and the blue light electroluminescent unit is connected with the power control module.

16. The display device according to claim 15, wherein
the red light electroluminescent unit, the green light electroluminescent unit and the blue light electroluminescent unit are organic light emitting diodes, an anode of each organic light emitting diode is connected with a corresponding drive transistor, and a cathode of the each organic light emitting diode is connected with the power control module.

17. A display driving method, comprising steps of:
detecting a temperature in a temperature detection region of a temperature sensor; and
inquiring a preset temperature and cathode voltage relationship table based on the detected temperature and controlling a cathode voltage for at least one sub-pixel unit within the temperature detection region.

18. The display driving method according to claim 17, wherein the step of inquiring the preset temperature and cathode voltage relationship table based on the detected temperature and controlling the cathode voltage for the at least one sub-pixel unit within the temperature detection region comprises:
inquiring the preset temperature and cathode voltage relationship table and decreasing the cathode voltage for the at least one sub-pixel unit within the temperature detection region, in a case that the detected temperature increases; and
inquiring the preset temperature and cathode voltage relationship table and increasing the cathode voltage for the at least one sub-pixel unit within the temperature detection region, in a case that the detected temperature decreases.
